(19) United States
(12) Patent Application Publication
(10) Pub. No.: US 2002/0122507 A1
(43) Pub. Date: Sep. 5, 2002

(54) System for carrier phase tracking of multi-dimensional coded symbols

(76) Inventor: Donald Brian Eidson, San Diego, CA (US)

Correspondence Address: HOWREY SIMON ARNOLD & WHITE LLP, BOX 34, 1299 PENNSYLVANIA AVENUE NW, WASHINGTON, DC, 20004, US

(21) Appl. No.: 09/738,896

(22) Filed: Dec. 15, 2000

(51) Int. Cl. H03D 1/00; H04L 27/06

(52) U.S. Cl. 375/340

(57) ABSTRACT

A system for determining an estimate of a multi-dimensional symbol, and one or more residuals between the symbol and the estimate. The one or more of the residuals may be weighted by the reliability metric for the multi-dimensional symbol. The residuals, weighted or unweighted, may then be used to update a derotation phase or phase offset estimate. The individual symbols in the multi-dimensional symbol may then be derotated responsive to the derotation phase or phase offset estimate.

### BACKGROUND OF THE INVENTION

1. Field of the Invention

This invention generally relates to multi-dimensional, coded symbols, and, more specifically, to carrier phase tracking of such symbols.

2. Related Art

The carrier phase of a signal can meander with time, due to instabilities in the transmitter upconversion circuitry, or instabilities in the demodulator oscillator and downconversion circuitry. The presence of this phase noise degrades the performance of receiver, by creating a phase rotation in the actual signaling constellation with respect to the assumed signaling constellation. Since the phase noise typically varies at a much slower rate than the transmitted symbol rate, this phase noise trend can often be estimated (e.g. “tracked”), and subsequently compensated for by circuits within the receiver.

Conventional tracking loops typically operate on one symbol at a time. A symbol is compared to an estimate of the symbol, and a phase adjustment made to the next symbol in response to this comparison. The frequency at which the loop is updated is typically the frequency at which new symbols are introduced to the tracking loop.

A multi-dimensional symbol is essentially a plurality of symbols that bear a logical relationship to one another in that all are encoded from the same group of underlying source bits. Conventional tracking loops process multi-dimensional symbols by processing each of the individual symbols in the plurality one at a time. This approach is not optimal because it ignores the fact that the symbols bear a logical relationship to one another. It is also computationally burdensome because some of the analysis performed on each symbol is redundant and unnecessarily repeated from symbol to symbol.

### SUMMARY

The invention provides a system for carrier phase tracking of multi-dimensional coded symbols. A multi-dimensional symbol is input to a symbol estimation module. The multi-dimensional symbol can be represented by the vector rₖ^{D}, where the subscript k indicates time, and the superscript D indicates that the vector comprises a plurality D of individual constituent symbols. The symbol estimation module provides an estimate for the multi-dimensional channel symbol. The estimate itself may be multi-dimensional, and represented by the vector sₖ^{D}. This indicates that estimates of the individual constituent symbols are included within or easily derivable from sₖ^{D}.

The multi-dimensional symbol estimate sₖ^{D} may be formed from any device capable of producing soft symbol estimates, including, without limitation, a MAP decoder, a log-MAP decoder, a SISO decoder, a SOVA decoder, a Viterbi decoder, or the like. In one implementation, a modified log-MAP decoder is used where only the alpha (forward recursion) engines are utilized.

A residual determination module forms a multi-dimensional residual indicating a difference between the symbol rₖ^{D} and the estimate sₖ^{D}. The residual may be a scalar zₖ and lack multiple dimensions, or it may be a vector zₖ^{D}, and have multiple dimensions, each representing a residual between an individual constituent symbol, and the estimate of that individual symbol. The residuals may be, without limitation, phase residuals or they may be orthogonal component residuals, i.e., the component of a symbol orthogonal to the estimate of that symbol.

A scalar reliability metric Rₖ, indicating the reliability of the multi-dimensional estimate, may also be provided by the symbol estimation module. The reliability metric may be used to weight the corresponding residuals. If the residual is the vector zₖ^{D}, the weighted residual may be represented by Rₖ·zₖ^{D}, indicating that Rₖ is used to weight each of the components of zₖ^{D}. If the residual is the scalar zₖ, the weighted residual may be represented by Rₖ·zₖ.

In one application, the tracking loop module then determines, responsive to one or more of the weighted or unweighted residuals, a derotation phase θₖ for the multi-dimensional symbol. This derotation phase may be a scalar θₖ, which applies to each of the individual symbols in the multi-dimensional symbol. Or it may be a multi-dimensional vector θₖ^{D}, including individual derotation phases for each of the individual constituent symbols in the multi-dimensional symbol. In another application, the tracking loop module then determines, responsive to the weighted or unweighted residuals, a phase offset estimate for the multi-dimensional symbol. The phase offset estimate may be a scalar Δθₖ, which applies to each of the individual symbols of the multi-dimensional symbol rₖ^{D}. Or it may be a vector Δθₖ^{D}, with individual phase offset estimates for each of the individual constituent symbols in the multi-dimensional symbol. These derotation phases or phase offset estimates may be used to derotate the individual symbols in the multi-dimensional symbol to reduce or eliminate phase offset with respect to the carrier.

In one example, the residual which is produced is the vector zₖ^{D}, and the same reliability metric Rₖ is used to weight each of the components of the vector zₖ^{D}. The tracking loop module in this example determines an individual component of θₖ^{D} or Δθₖ^{D}, as the case may be, responsive to the corresponding individual weighted residual. In other words, it determines θₖⁱ or Δθₖⁱ, 1≦i≦D, responsive to Rₖ·zₖⁱ, 1≦i≦D.

In a second example, a function of the individual component residuals of zₖ^{D} is formed. Such a function may be designated as f(zₖ^{D}). For example, f(zₖ^{D}) may be the average of the individual component residuals. This function may be weighted by the reliability metric for the multi-dimensional channel symbol. The tracking loop module may then determine a scalar derotation phase θₖ or phase offset estimate Δθₖ responsive to the value Rₖ·f(zₖ^{D}). This value may then be applied to each of the individual symbols in the multi-dimensional symbol.

In a third example, a composite residual is formed for a multi-dimensional symbol. The composite residual may be a phase residual or an orthogonal component residual. The composite residual may be weighted by the reliability metric for the multi-dimensional symbol. The weighted value may be used to update the derotation phase once for the multi-dimensional symbol, or once for each of the individual symbols in the multi-dimensional symbol rₖ^{D}.

Other systems, methods, features and advantages of the invention will be or will become apparent to one with skill in the art upon examination of the following figures and detailed description. It is intended that all such additional systems, methods, features and advantages be included within this description, be within the scope of the invention, and be protected by the accompanying claims.

### BRIEF DESCRIPTION OF THE FIGURES

The invention can be better understood with reference to the following figures. The components in the figures are not necessarily to scale, emphasis instead being placed upon illustrating the principles of the invention. Moreover, in the figures, like reference numerals designate corresponding parts throughout the different views.

FIG. 1 is a block diagram of a TCM encoding system based on a rate k/n encoder.

FIG. 2 illustrates a rate 6/6 systematic convolutional encoder.

FIG. 3 illustrates the two 8-PSK symbol constellations for each of the 8-PSK symbols output by the encoder of FIG. 5.

FIG. 4A is a block diagram of a system in accordance with the subject invention.

FIG. 4B is a block diagram of an application of the system of FIG. 4A.

FIGS. 5A-5C illustrate examples of the computation of a weighted phase residual.

FIGS. 6A-6C illustrate examples of the computation of a weighted orthogonal component residual.

FIG. 7 is a flowchart of a method of computing reliability metrics for a multi-dimensional channel symbol.

FIG. 8 is a portion of a trellis diagram illustrating an example of recursive calculation of forward probabilities.

FIG. 9 is a portion of a trellis diagram illustrating an example of recursive calculation of backward probabilities.

FIG. 10 is a portion of a trellis diagram illustrating an example of calculation of joint probabilities from the forward, backward, and edge probabilities.

FIG. 11 is a portion of an example trellis diagram illustrating, for a two-state, symmetric trellis, computation of log-likelihood values.

### DETAILED DESCRIPTION

A. Multi-Dimensional Channel Symbols

Multi-dimensional channel symbols are channel symbols which have multiple dimensions that bear a relationship to one another. Typically, this relationship derives from the fact that the multiple dimensions are encoded from the same underlying source bits. Multi-dimensional channel symbols may be produced by a trellis-coded modulation (TCM) encoding system. The TCM encoding system may in turn incorporate a rate k/n convolutional encoder.

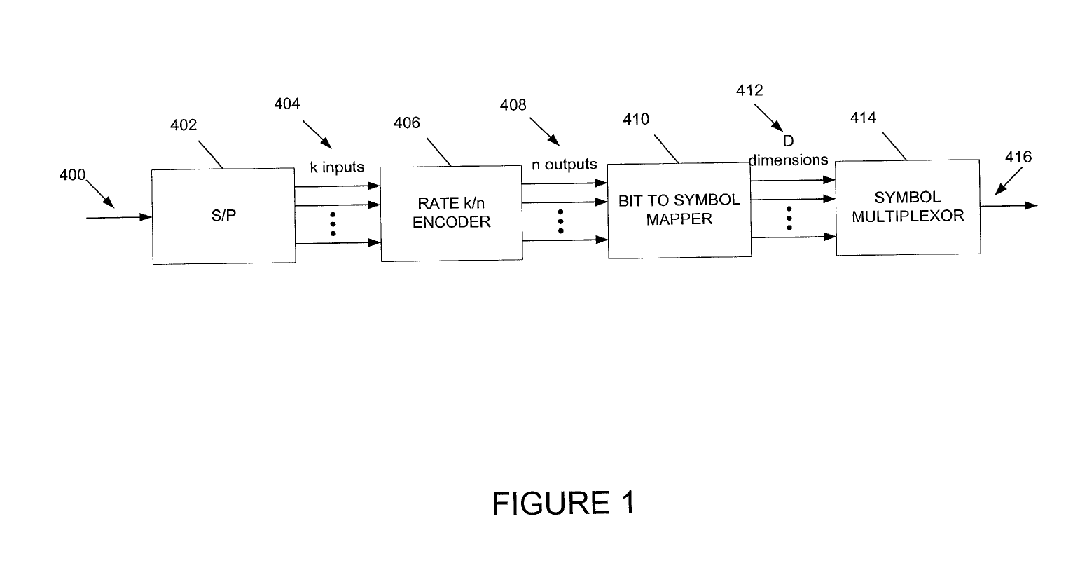

FIG. 1 illustrates a TCM encoding system which incorporates a rate k/n encoder. In general, the integer k is less than or equal to the integer n. The ratio of k to n relates to the redundancy of the symbols coded by the encoder. The greater this ratio of source bits to coded bits, the less redundancy is built into the encoded symbols.

As illustrated, the TCM encoding system comprises a serial to parallel (S/P) converter 402, a rate k/n encoder 406, a bit to symbol mapper 410, and, optionally, a symbol multiplexor 414. Incoming source bits 400 are serially input to S/P converter 402. S/P converter 402 converts the serial stream of input bits to successive parallel renditions of k bits each. Each k bit rendition 404 is input to a rate k/n encoder 406. The output of the rate k/n encoder comprises successive parallel renditions of n bits each. Each n bit rendition 408 is input to bit to symbol mapper 410. Bit to symbol mapper 410 converts each rendition 408 of n bits to a D-dimensional channel symbol, where D is an integer equal to 1 or more. In the case in which D=1, the symbol multiplexor 414 is unnecessary. In the case in which D>1, the symbol multiplexor 414 serializes the D components of a D-dimensional symbol and outputs the same on signal line 416. In one implementation, the multiplexor serializes the D components two at a time to represent the I and Q components of a quadrature output.

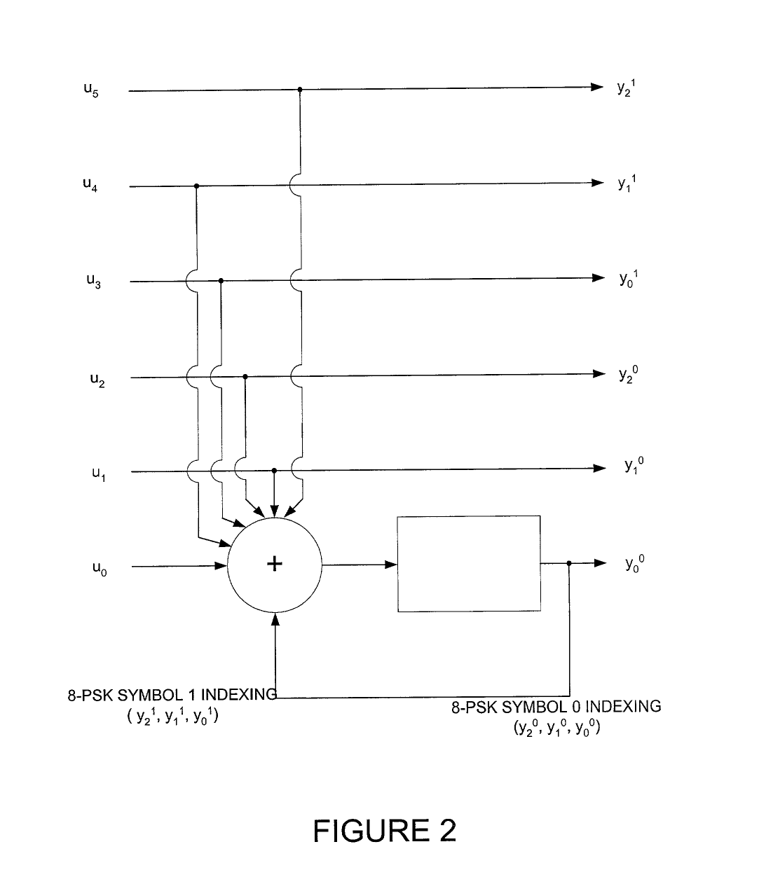

FIG. 2 illustrates an example of a rate k/n encoder which can be used in the TCM encoding system of FIG. 1. The particular example shown is a rate 6/6 systematic, convolutional encoder. As illustrated, the input to the encoder is a 6-tuple of input bits which can be represented by (u₅, u₄, u_{3,} u_{2,} u₁, u₀), and the output of the encoder is an output symbol comprising a 6-tuple of output bits which can be represented as (y₂¹, y₁¹, y₀¹, y₂⁰, y₁⁰, y₀⁰).

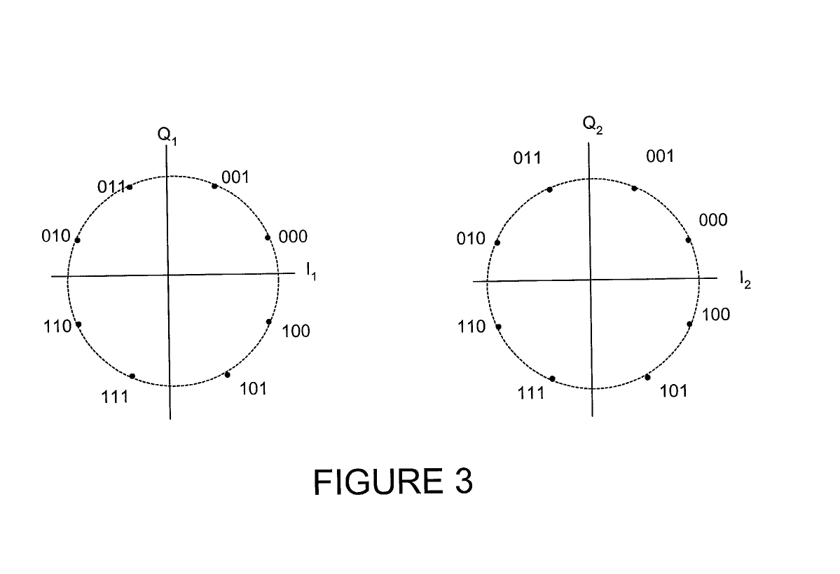

The 6 output bits of the encoder can be grouped into two 3-tuples, represented respectively as (y₂¹, y₁¹, y₀¹) and as (y₂⁰, y₁⁰, y₀⁰), and the mapper 410 maps each such 3-tuple into an 8-PSK symbol. Each of the two 8-PSK symbols is a quadrature symbol having I and Q components. A 6-tuple output symbol can be considered to be a single four-dimensional symbol, since each output symbol is comprised of two 8-PSK symbols, and each 8-PSK symbol is represented in two dimensions on the (I and Q) complex plane. FIG. 3 illustrates the functioning of the bit to symbol mapper 410 in this example. The particular mapping which is used can be represented by the following table:

| 3-tuple (y₂ⁱ, y₁ⁱ, y₀ⁱ), i = 0, 1 | 8-PSK symbol |
|---|---|
| (0, 0, 0) | π/16 |
| (0, 0, 1) | 3π/16 |
| (0, 1, 1) | 5π/16 |
| (0, 1, 0) | 7π/16 |
| (1, 1, 0) | 9π/16 |
| (1, 1, 1) | 11π/16 |
| (1, 0, 1) | 13π/16 |
| (1, 0, 0) | 15π/16 |

In this particular example, a Gray mapping is employed, in which adjacent symbols correspond to 3-tuples which differ by no more than a single bit. An alternate Gray mapping is also possible with 8-PSK since, as is known, there are two unique Gray maps for 8-PSK. It should be appreciated, however, that, in the general case involving a rate k/n (or n/n) encoder, Gray mapping need not be employed.

This example can easily be generalized to other cases. Consider, for example, a rate 4/4 encoder in which the four bits output by the encoder are grouped into two 2-bit tuples, each of which is mapped into a QPSK symbol. Again, an output symbol can be considered to be a single 4-dimensional symbol, since two QPSK symbols are output, and each symbol is two-dimensional.

Next, consider a rate 12/12 encoder in which the 12 bits output by the encoder are grouped into 3 4-bit tuples, each of which is mapped into a 16-QAM symbol. An output symbol can be considered to be a 6-dimensional symbol, since each output symbol is comprised of three 16-QAM symbols, and each 16-QAM symbol is two-dimensional, i.e., is represented by I and Q coordinates.

Note that, in general, a multidimensional code is a rate k/n code where k<n, and n is evenly divisible by the number of constellation points within a modulation symbol (e.g., 4 constellation points for a single QPSK-modulated symbol). Here, examples involving rate n/n codes have been used simply for ease of illustration. However, examples of the more general k/n case can easily be extrapolated from this disclosure.

B. Embodiments of the Invention

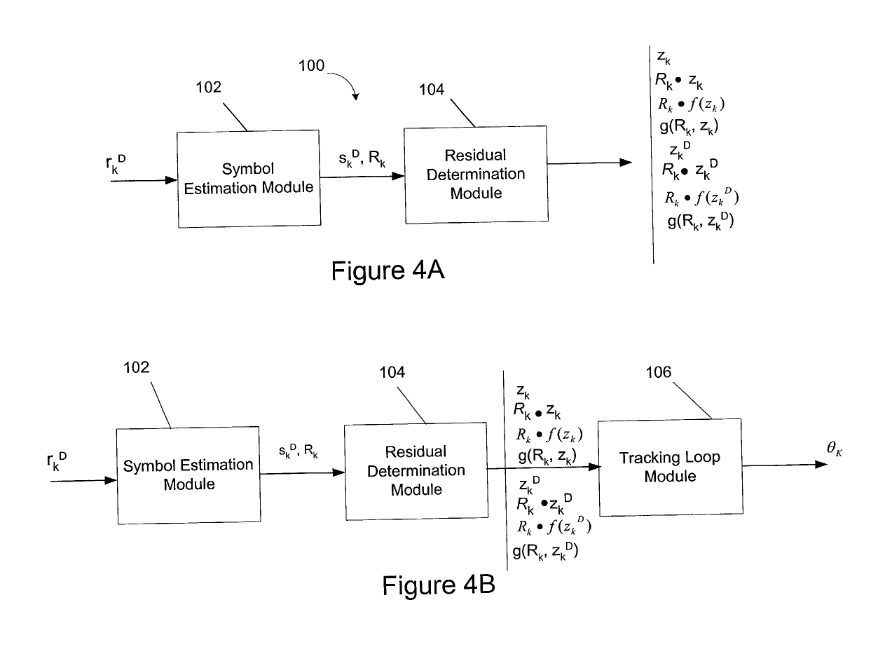

A first embodiment of a system 100 in accordance with the invention is illustrated in FIG. 4A. As illustrated, the system 100 comprises a symbol estimation module 102 coupled to a residual determination module 104. A multi-dimensional symbol is input to the symbol estimation module 102. The multi-dimensional symbol can be represented by the vector rₖ^{D}, where the subscript k indicates time, and the superscript D indicates that the vector comprises a plurality D of individual constituent symbols. The symbol estimation module 102 provides an estimate for the multi-dimensional channel symbol. The estimate itself may be multi-dimensional, and represented by the vector sₖ^{D}. This indicates that estimates of the individual constituent symbols are included within or easily derivable from sₖ^{D}.

The residual determination module 104 forms a multi-dimensional residual indicating a difference between the symbol rₖ^{D} and the estimate sₖ^{D}. The residual may be a scalar zₖ and lack multiple dimensions, or it may be a vector zₖ^{D}, and have multiple dimensions, each representing a residual between an individual constituent symbol, and the estimate of that individual symbol. A function of the vector zₖ^{D} which can be designated f(zₖ^{D}), may also be provided by module 104. The residuals may be, without limitation, phase residuals or they may be orthogonal component residuals, i.e., the component of a symbol orthogonal to the estimate of that symbol.

A reliability metric Rₖ, indicating the reliability of the multi-dimensional estimate, may also be provided by the symbol estimation module 102. The reliability metric may be used by the residual determination module 104 to weight the corresponding residuals. If the residual is the vector zₖ^{D}, the weighted residual may be represented by Rₖ·Zₖ^{D}, indicating that Rₖ is used to weight each of the components of zₖ^{D}. If the residual is the scalar zₖ, the weighted residual may be represented by Rₖ·zₖ. If a function f(zₖ^{D}) is computed, the weighted value Rₖ·f(zₖ^{D}) may be provided by module 104. Module 104 may also form a joint function of the reliability metric Rₖ and the residual zₖ^{D}, which is designated g(Rₖ, zₖ^{D}) in the figure. One of ordinary skill in the art will appreciate from a reading of this disclosure that many more example are possible.

In one application, illustrated in FIG. 4B, a phase determination module 106 is provided which determines, responsive to one or more of the weighted or unweighted residuals from module 104, a derotation phase for the multi-dimensional symbol. This derotation phase may be a scalar θₖ, which applies to each of the individual symbols in the multi-dimensional symbol. Or it may be a multi-dimensional vector θₖ^{D}, including individual derotation phases for each of the individual constituent symbols in the multi-dimensional symbol. These derotation phases may be used to derotate the individual symbols in the multi-dimensional symbol to reduce or eliminate phase offset with respect to the carrier.

In this application, the residual determination module and the phase determination module 106 may together form a tracking loop module 108. The derotation phase output from the tracking loop module 108 may be used to derotate the individual symbols in the multi-dimensional symbol rₖ^{D} as described in any of the embodiments employing feedfoward tracking loops disclosed in Howrey Dkt. No. 01827.0042.US00, Conexant Dkt. No. 00CXT0361D, or Howrey Dkt. No. 01827.0043.US00, Conexant Dkt. No. 00CXT0362D, both previously incorporated herein by reference.

In another application, also illustrated in FIG. 4B, a phase determination module 106 is provided which determines, responsive to the weighted or unweighted residuals, a phase offset estimate for the multi-dimensional symbol. The phase offset estimate may be a scalar Δθₖ, which applies to each of the individual symbols of the multi-dimensional symbol rₖ^{D}. Or it may be a vector Δθₖ^{D}, with individual phase offset estimates for each of the individual constituent symbols in the multi-dimensional symbol. These phase offset estimates may be used to derotate the individual symbols in the multi-dimensional symbol to reduce or eliminate phase offset with respect to the carrier.

In this application, the residual determination module and the phase determination module 106 may together form a tracking loop module 108. The phase offset estimates output from the tracking loop module 108 may be used by an accumulator to form derotation phases which in turn are used to derotate the individual symbols in the multi-dimensional symbol rₖ^{D} as described in any of the embodiments employing feedback tracking loops disclosed in Howrey Dkt. No. 01827.0042.US00, Conexant Dkt. No. 00CXT0361D, or Howrey Dkt. No. 01827.0043.US00, Conexant Dkt. No. 00CXT0362D, both previously incorporated herein by reference.

The module 102 may be any device capable of producing soft symbol estimates, including, without limitation, a MAP decoder, a log-MAP decoder, a Soft Input Soft Output (“SISO”) decoder, a SOVA decoder, a max-log MAP decoder, or the like. Module 102 may also be a Viterbi decoder where a reliability metric is derived from the best path metric minus the second-best path metric. In one implementation, a modified log-MAP decoder is used where only the alpha (forward recursion) engines are utilized. Additional information about the log-MAP decoding process is available in U.S. patent application Ser. No. Not Yet Assigned, Howrey Dkt. 01827.0041.US00, Conexant Dkt. No. 00CXT0360D, and U.S. patent application Ser. No. Not Yet Assigned, Howrey Dkt. No. 01827.0042.US00, Conexant Dkt. No. 00CXT0361D, both of which were previously incorporated herein by reference.

In a second embodiment of the invention, the symbol estimation module is a maximum a posteriori (MAP) decoder which utilizes a MAP algorithm to determine an estimate of a multi-dimensional channel symbol, and, optionally, a reliability metric for the estimate. For additional details on MAP decoders, the reader is referred to “Optimal Decoding of Linear Codes for Minimizing Symbol Error Rate,” L. R. Bahl et al., IEEE Transactions on Information Theory, March 1974, pp. 27-30 (hereinafter referred to as “the Bahl reference”); “Near Shannon Limit Error-Correcting Coding and Decoding: Turbo Codes,” C. Berrou et al., Proc. ICC '93 Geneva, Switzerland, May 1993, pp. 1064-1070 (hereinafter referred to as “the Berrou reference”); “An Intuitive Justification and a Simplified Implementation of the MAP Decoder for Convolutional Codes,” A. Viterbi, IEEE Journal On Selected Areas In Telecommunications, Vol. 16, No. 2, Feb. 1998, pp. 260-264 (hereinafter referred to as “the Viterbi reference”); and J. Hagenauer and P. Hoeher, “A Viterbi Algorithm with Soft-decision outputs and its applications,” in Proceedings of IEEE Globecom '89, Dallas, Tex., Nov. 1989, pp. 47.1.1-47.1.7. (“the Hagenauer reference”) Each of the Bahl, Berrou, Viterbi, and Hagenauer references are hereby fully incorporated by reference herein as though set forth in full.

The MAP decoder may be a log-MAP decoder in which the underlying probabilities are expressed in the natural-log domain. Log domain probabilities are advantageous since they ease computational burden. For example, with log domain probabilities, joint probabilities can be computed through addition rather than multiplication. It should be appreciated, however, that the process can easily be generalized to the case in which the probabilities are expressed in terms of their normal domains.

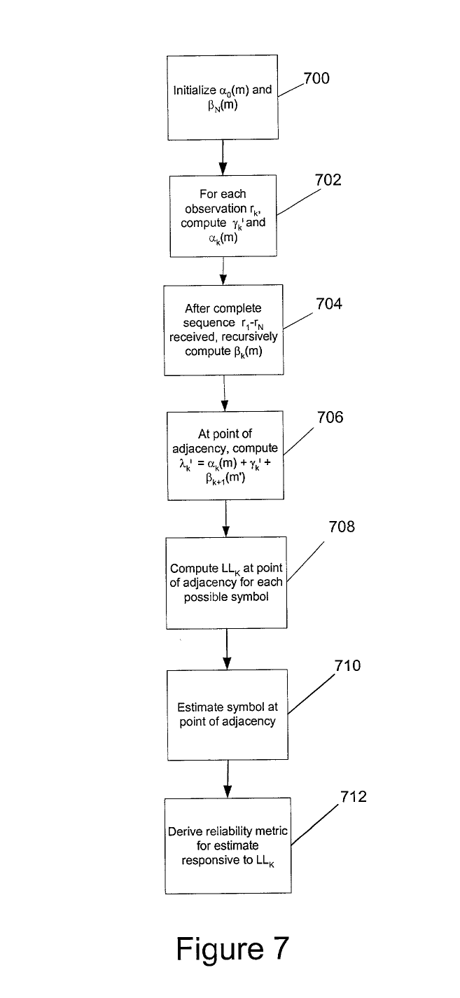

A flowchart of one embodiment of the process employed by this log-MAP decoder is illustrated in FIG. 7. In this flowchart, the notation αₖ(m) refers to the natural log domain (hereinafter referred to as “log domain”) forward probability of being in state m at time k; γₖⁱ refers to the log domain edge probability for edge i at time k; and βₖ(m) refers to the log domain reverse probability of being in state m at time k. It is assumed that a block of N multi-dimensional channel symbols is processed at a time.

In step 700, the boundary values α₀(m) and β_{N}(m) are initialized for all values of m.

In step 702, for each observation rₖ, αₖ(m) and γₖⁱ are computed for all values of m and i. Note that the “observation” rₖ is a multi-dimensional channel symbol as perturbed by noise through passage through the channel. Advantageously, the forward probabilities αₖ(m) are computed recursively as a function of αₖ₋₁(m). In one implementation, this step may be performed using equations (21) and (23) from the Berrou reference.

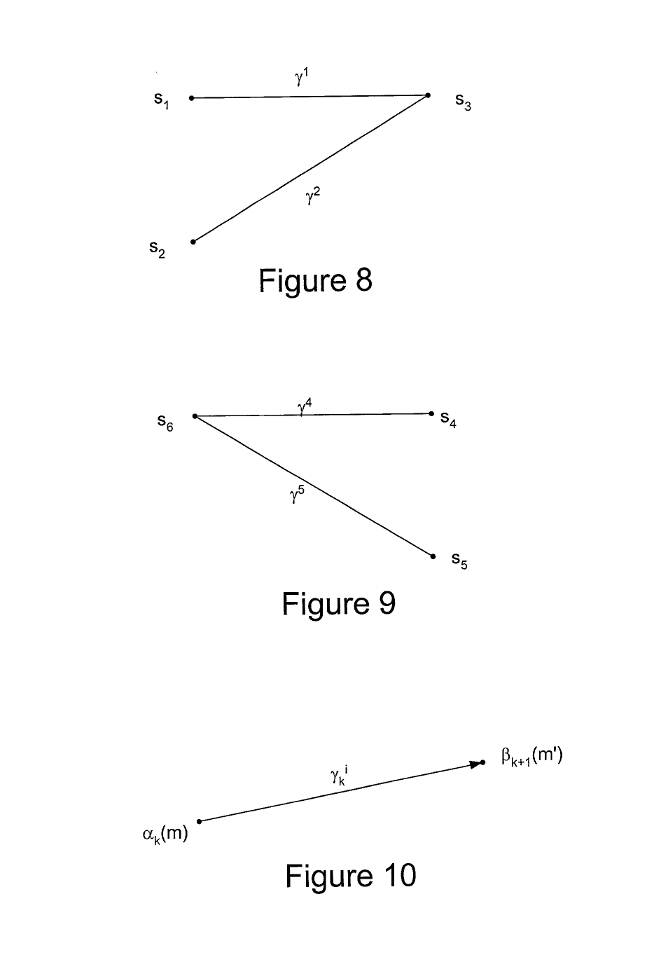

An example of the computation of forward probabilities is illustrated in FIG. 8. In this example, there are two permissible branches into state s₃, one from state s₁ and one from state s₂. The log domain probability of s₁, α(1), and the log domain probability of s₂, α(2), have been previously determined. Similarly, the log domain edge probabilities γ¹ and γ² have been previously determined. The objective is to compute the log domain probability of the state s₃, α(3), from the foregoing parameters.

In this example, the calculation of the probability α(3) can be expressed using the following equation:

α(3)=MAX*(α(1)+α¹,α(2)+γ²)

where the function MAX*(A,B) is defined to be:

MAX*(A,B)≡MAX(A,B)+ln(1+exp(−|A−B|))

Turning back to FIG. 7, in step 704, the reverse probabilities βₖ(m) are computed for all values of m. The probabilities βₖ(m) are advantageously computed recursively as a function of βₖ₊₁(m). In one implementation, this step may be performed using equation (22) from the Berrou reference.

An example of the computation of reverse probabilities is illustrated in FIG. 9. In this example, there are two permissible branches into state s₆, one from state s₄ and one from state s₅. The log domain probability of s₄, β(4), and the log domain probability of s₅, β(5), have been previously determined. Similarly, the log domain edge probabilities γ⁴ and γ⁵, have been previously determined. The objective is to compute the log domain probability of the state s₆, β(6), from the foregoing parameters.

In this example, the calculation of the natural log domain probability β(6) can be expressed using the following equation:

β(6)=MAX*(β(4)+γ⁴,β(5)+γ⁵)

where the function MAX*(A,B) is defined as before.

Turning back to FIG. 7, in step 706, at the point where the forward and reverse probabilities are about to overlap, i.e., a point of adjacency, the joint log domain probabilities λₖⁱ=αₖ(m)+γₖⁱ+βₖⁱ+αₖ₊₁(m′) are computed for all edges at the point of adjacency. An example of this process is illustrated in FIG. 10. Referring to the leftmost state as state m at time k, and the rightmost state as state m′ at time k+1, it is assumed that the forward state log domain probability αₖ(m), the reverse state log domain probability βₖ₊₁(m′), and the edge log domain probability γₖⁱ have all been computed. This step involves adding these probabilities, i.e., performing the computation λₖⁱ=αₖ(m)+γₖⁱ+βₖ₊₁(m′) in order to compute the joint log domain probability of transitioning between the two states along the prescribed edge.

Turning back to FIG. 7, step 706 is followed by step 708. In step 708, a log-likelihood, LLₖ, is determined at the point of adjacency for each of the possible symbols. The log-likelihood for a symbol S at time k, LLₖ(S), may be expressed by the following equation:

LLₖ(S)=MAX*_{∀i that imply release of symbol}S(λₖⁱ)−MAX*_{∀i}(λₖⁱ)

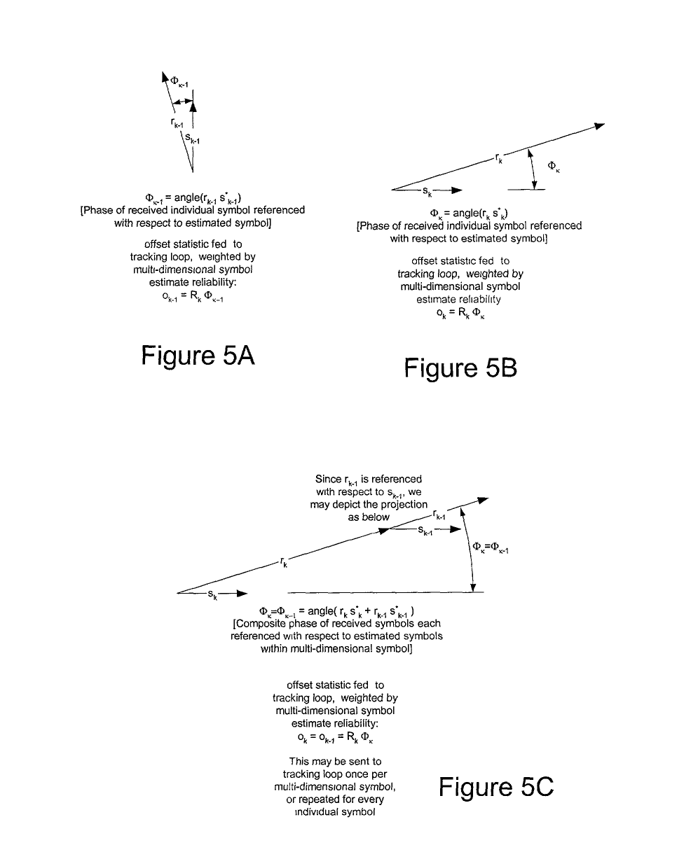

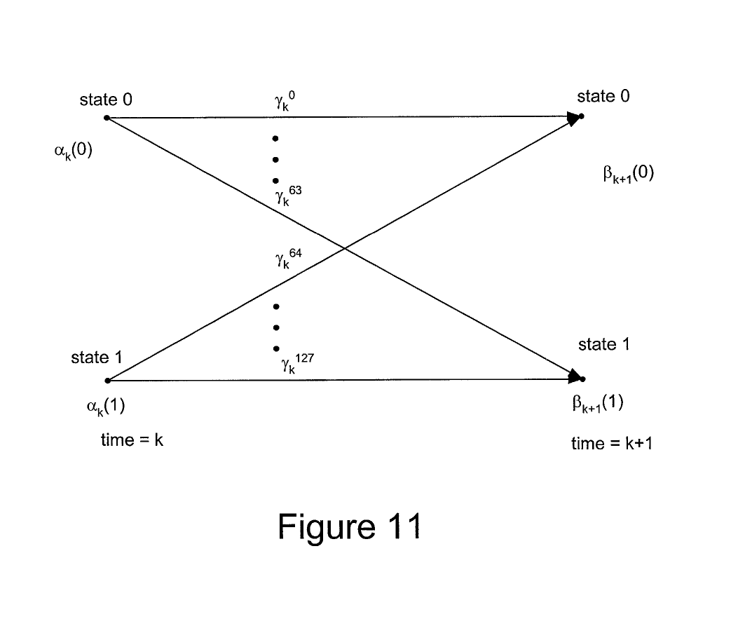

This step can be explained with reference to FIG. 11, which illustrates a portion of a trellis diagram for a log-MAP decoder configured in accordance with the invention. The particular example shown is a trellis diagram for a decoder configured for use in conjunction with the rate 6/6 encoder of FIG. 5. Since there is only one storage element in the encoder, there are only two possible states of the encoder at a point in time, 0 or 1. Note that, in general, the state transitions are not symmetric as illustrated. Instead, in the general case for non-systematic codes involving more than two states, the trellis diagram exhibits a more elaborate “butterfly” pattern.

The leftmost portion of FIG. 11 represents time k, and the rightmost portion represents time k+1. The two possible states at time k are indicated as state 0 and state 1, respectively, as are the two possible states at time k+1. It is assumed that the portion of the trellis illustrated in FIG. 11 is at the point of adjacency in the calculation of forward and reverse state probabilities. Thus, for time k, the forward state probabilities αₖ(0) and αₖ(1) have been computed for states 0 and 1, respectively. Similarly, for time k+1, the backward state probabilities αₖ₊₁(0) and βₖ₊₁(1) have been computed for states 0 and 1, respectively.

In addition, the edge probabilities γₖⁱ have all been computed, as have the joint probabilities λₖⁱ. In an encoder with k inputs and m storage elements, there will be 2^{k}·2^{m} possible edge transitions at a given point in time. For the encoder of FIG. 5, consistent with this formula, there will be 128 possible edge transitions for a given point in time. This is reflected in the trellis diagram of FIG. 11, in which 128 edge transitions are indicated, 64 emanating from state 0 at time k, and 64 emanating from state 1 at time k. These edges are all assigned a unique index ranging from 0 to 127. The corresponding edge probabilities are referred to as γₖⁱ, where i ranges from 0 to 127. Similarly, the corresponding joint probabilities are referred to as λₖⁱ, where i ranges from 0 to 127.

Each of the edges is consistent with the release of a channel symbol. For an encoder with an n-tuple output, there are 2ⁿ possible values of channel symbols. Consistent with this, in the encoder of FIG. 5, there are 64 possible channel symbols. If the number of possible edge transitions at a point in time exceeds the number of possible channel symbols, there will be some edges which are consistent with the release of the same channel symbol. For the encoder of FIG. 5, there will be two transitions which are consistent with the release of the same channel symbol. The possibility that more than one edge may imply release of the same symbol is reflected in the first MAX* term equation (1) above.

Turning back to FIG. 7, step 708 is followed by step 710, in which the channel symbol at time k is estimated, along with the reliability metric for that symbol, responsive to the LLₖ values computed in the previous step. In one embodiment, the estimated symbol is taken to be the symbol p which corresponds to the maximum value of LLₖ. This condition may be represented by the following equation:

LLₖ(p)=MAX_{∀ possible channel symbols s}(LLₖ(S))

Step 710 is followed by step 712, when a reliability metric for the estimate p is derived from LLₖ(p). The reliability metric for p may be equal to LLₖ(p). Alternatively, that metric may be set equal to exp(LLₖ(p)). In general, other examples are possible where the reliability metric is a function of LLₖ.

The foregoing process may then be repeated at other points of adjacency in the trellis diagram and for additional blocks of incoming symbols. In one embodiment, the process iterates until each of the symbols in a block is estimated, and reliability metrics for each of these estimates determined. Then, the process may be repeated for additional blocks.

In a third embodiment of the invention, the engine 104 is a modified log-MAP decoder in which only the alpha (forward recursion) engines function. These alpha engines compute the forward recursive probabilities αₖ(m) and the edge probabilities γₖⁱ. Then, they compute the joint probabilties λₖⁱ in accordance with the following equation: λₖⁱ=αₖ(m)+γₖⁱ. The log-likelihoods, LLₖ, are then computed from the joint probabilities λₖⁱ as described in the previous embodiment. The reliability metrics for the multi-dimensional symbols are then computed as described in the previous embodiment.

A computer readable medium which tangibly embodies the method steps of any of the foregoing embodiments is within the scope of the invention. Such a medium may include, without limitation, RAM, ROM, EPROM, EEPROM, floppy disk, hard disk, CD-ROM, etc. The invention also includes the method steps of any of the foregoing embodiments synthesized as digital logic in an integrated circuit, such as an FPGA, or PLA, for example.

Several advantages flow from the production of a single estimate for all dimensions of a multi-dimensional channel symbol rather than separate estimates for the different dimensions of the symbol. First, the approach is more efficient from a computational standpoint. Second, it is more accurate since, in effect, it uses distance statistics in multi-dimensional space to determine an estimate of a multi-dimensional symbol. In contrast, in an approach where an estimate is separately produced for each constituent symbol, the distances used amount to projections of true distances onto a plane. In some instances, this could result in a less accurate estimate, or diminished tracking performance by the tracking loop.

### C. EXAMPLES

In one example of the operation of residual determination module 104, the residual which is produced is the vector zₖ^{D}, and the same reliability metric Rₖ is used to weight each of the components of the vector zₖ^{D}. The tracking loop module in this example determines an individual component of θₖ^{D} or Δθₖ^{D}, as the case may be, responsive to the corresponding individual weighted residual. In other words, it determines θₖ¹ or Δθₖⁱ, 1≧i≧D, responsive to Rₖ·zₖⁱ, 1≧i≧D.

In a second example, a function of the individual component residuals of zₖ^{D} is formed. Such a function may be designated as f(zₖ^{D}). For example, f(zₖ^{D}) may be the average of the individual component residuals. This function may be weighted by the reliability metric for the multi-dimensional channel symbol. The tracking loop module may then determine a scalar derotation phase ok or phase offset estimate Γθₖ responsive to the value Rₖ·f(zₖ^{D}). This value may then be applied to each of the individual symbols in the multi-dimensional symbol.

In a third example, a composite residual is formed for a multi-dimensional symbol. The composite residual may be a phase residual or an orthogonal component residual. The composite residual may be weighted by the reliability metric for the multi-dimensional symbol. The weighted value may be used to update the derotation phase once for the multi-dimensional symbol, or once for each of the individual symbols in the multi-dimensional symbol rₖ^{D}.

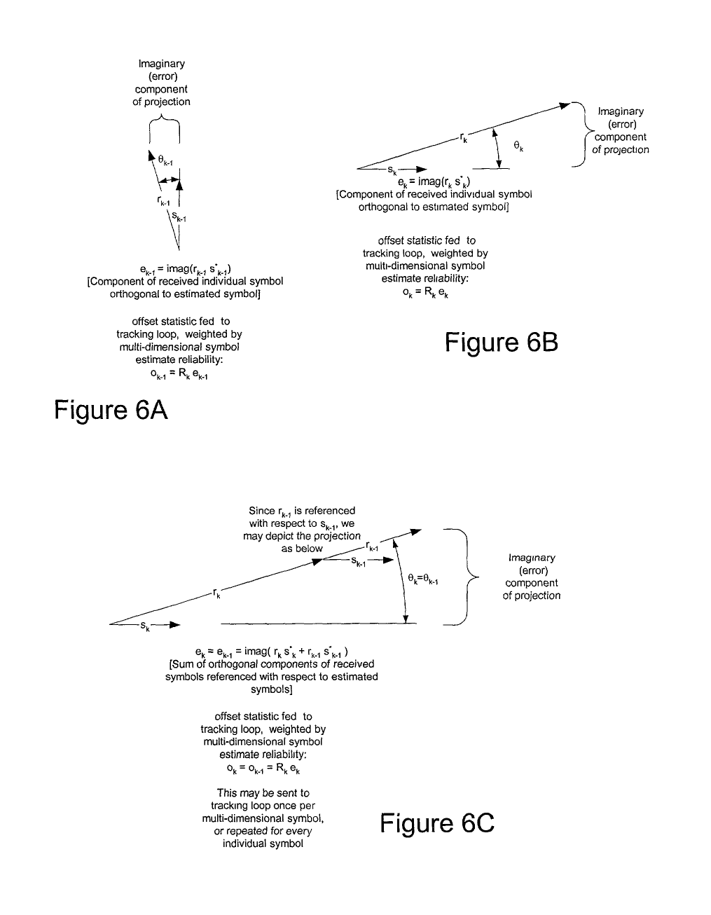

FIGS. 5A-5C and 6A-6C illustrate several additional examples of the operation of residual determination module 104. In FIG. 5A, a phase residual Φₖ₋₁ between the individual symbol rₖ₋₁ and as estimate of that symbol sₖ₋₁ is determined in accordance with the following expression:

Φₖ₋₁=angle(rₖ₋₁s*ₖ₋₁)

where * is the complex conjugate relation. This phase residual may be weighted by the reliability metric Rₖ for the multi-dimensional symbol of which the individual symbol rₖ₋₁ is a part in order to determine oₖ₋₁, the input to the phase determination module 106.

In FIG. 5B, a phase residual Φₖ between the individual symbol rₖ and the estimate of that symbol sₖ is determined in accordance with the following expression:

Φₖ=angle(rₖsₖ*)

where * is the complex conjugate operation. This phase residual may be weighted by the reliability metric Rₖ for the multi-dimensional symbol of which the individual symbol rₖ is a part in order to determine Ok, an input to the phase determination module.

FIG. 5C illustrates another approach in which the composite phase residual Φₖ for both individual symbols rₖ₋₁ and rₖ may be determined in accordance with the following expression:

Φₖ=angle(rₖs*ₖ+rₖ₋₁s*ₖ₋₁)

This composite phase residual Φₖ may then be weighted by the reliability metric Rₖ for the multi-dimensional symbol comprising the individual symbols rₖ₋₁ and rₖ to form the input oₖ to the phase determination module. This value may be input to the phase determination module once for the multi-dimensional symbol comprising rₖ₋₁ and rₖ, or twice, once for rₖ₋₁ and once for rₖ.

Note that, since the underlying phase intended to be tracked will generally not vary much from symbol to symbol, the composite phase residual of FIG. 5C will typically be about equal to either of the phase residuals computed in FIGS. 5A and 5B—when no additive noise (such as AWGN) is present.

In FIG. 6A, the orthogonal component residual eₖ₋₁, the component of the individual symbol rₖ₋₁ which is orthogonal to the estimated symbol sₖ₋₁, is formed in accordance with the following expression:

eₖ₋₁=imag(rₖ₋₁s*ₖ₋₁)

where * is the complex conjugate operation. This component residual may then be weighted by the reliability metric Rₖ for the multi-dimensional symbol of which the individual symbol rₖ is a part to produce oₖ₋₁, the input to the phase determination module.

In FIG. 6B, the orthogonal component residual eₖ, the component of the symbol rₖ which is orthogonal to the estimated symbol sₖ, is formed in accordance with the following expression:

eₖ=imag(rₖiₖ*)

where * is the complex conjugate operation. This component residual may then be weighted by the reliability metric Rₖ for the multi-dimensional symbol of which the individual symbol rₖ is a part to form oₖ, the input to the parameter determination module.

FIG. 6C illustrates another approach in which a composite orthogonal component residual eₖ is formed in accordance with the following expression:

eₖ=imag(rₖs*ₖ+rₖ₋₁s*ₖ₋₁)

where * is the complex conjugate operation.

This composite orthogonal component residual may then be weighted by the reliability metric Rₖ for the multi-dimensional symbol to form the input oₖ to the parameter determination module. This value may be input to the phase determination module once for the multi-dimensional symbol comprising rₖ₋₁ and rₖ, or twice, once for rₖ₋₁ and once for rₖ.

Note that, if the phase noise process (carrier phase variation) is slow, the orthogonal component of individual symbols will generally not vary much from symbol to symbol, and so the composite orthogonal component residual of FIG. 6C will typically be about equal to the orthogonal components residuals of FIGS. 6A and 6B.

Examples are also possible in which statistics derived from vector operations on symbols may be used as inputs to the parameter determination module. Vectors of received symbols r=[rₖrₖ₋₁ . . . r_{N}] and estimated symbols s=[sₖsₖ₋₁ . . . s_{N}] may be assembled. Then, the statistic c=rs^{H}, where ‘H’ indicates the Hermetian (conjugate transpose operation), is performed. The result is a scalar, and can be expressed in scalar terms by c=rₖs*ₖ+rₖ₋₁s*ₖ₋₁+ . . . r_{N}S*_{N}. The phase of c may then be computed. This phase may then optionally be weighted by the reliability of the multi-dimensional symbol estimate, and the weighted value input to the phase determination module at the arrival/reception rate of multi-dimensional symbols. Alternately, this weighted value may be input to the phase determination module at the individual symbol arrival rate.

Also, in lieu of the phase of c, the imaginary part of c may be used to compute the input to the tracking loop. In particular, this imaginary part may be weighted by the multi-dimensional symbol reliability, and then input to the phase determination module at either the multi-dimensional or individual symbol arrival rate.

While various embodiments of the invention have been described, it will be apparent to those of ordinary skill in the art that many more embodiments and implementations are possible that are within the scope of this invention. Accordingly, the invention is not to be restricted except in light of the attached claims and their equivalents.

What is claimed is:

1. A system comprising:
a symbol estimation module for determining, for a multi-dimensional symbol rₖ^{D} having D dimensions, where D is an integer greater than 1, an estimate of the multi-dimensional symbol; and
a residual determination module coupled to the symbol estimation module for determining a residual or a function thereof for the multi-dimensional symbol responsive to the multi-dimensional symbol rₖ^{D}, and the estimate.

2. The system of claim 1 wherein the multi-dimensional symbol estimate comprises the vector sₖ^{D}.

3. The system of claim 1 wherein the multi-dimensional symbol estimate comprises the scalar sₖ.

4. The system of claim 1 wherein the residual comprises the residual vector zₖ^{D}.

5. The system of claim 1 wherein the residual comprises the scalar zₖ.

6. The system of claim 1 wherein the residual is a p has e residual.

7. The system of claim 1 wherein the residual is an orthogonal component residual.

8. The system of claim 5 wherein the residual zₖ is a composite residual.

9. The system of claim 1 wherein the residual determination module determines a function of the residual vector rₖ^{D}.

10. The system of claim 9 wherein the function is the average of the individual components of the residual vector rₖ^{D}.

11. The system of claim 1 wherein the system estimation module also determines a reliability metric Rₖ for the estimate of the multi-dimensional symbol, and weights the residual or function thereof using the reliability metric.

12. The system of claim 1 further comprising a phase determination module for determining a derotation phase responsive to the residual.

13. The system of claim 12 wherein the derotation phase is the vector θₖ^{D}.

14. The system of claim 12 wherein the derotation phase is the scalar θₖ.

15. The system of claim 1 further comprising a phase determination module for determining a phase offset estimate responsive to the residual.

16. The system of claim 15 wherein the phase offset estimate is the vector Δθₖ^{D}.

17. The system of claim 15 wherein the phase offset estimate is the scalar Δ←ₖ.

18. The system of claim 12 further comprising a symbol derotator for derotating each of the individual symbols in the vector rₖ^{D} responsive to the derotation phase.

19. The system of claim 15 further comprising an accumulator for determining a derotation phase responsive to the phase offset estimate.

20. The system of claim 19 further comprising a symbol derotator for derotating each of the individual symbols in the vector rₖ^{D} responsive to the derotation phase.

21. The system of claim 1 wherein the symbol estimation module comprises a decoder capable of producing soft estimates.

22. The system of claim 21 wherein the decoder is a log-MAP decoder.

23. The system of claim 12 wherein the phase determination module updates the derotation phase at the frequency of individual symbols in the multi-dimensional symbol.

24. The system of claim 15 wherein the phase determination module updates the derotation phase once for each multi-dimensional symbol.

25. The system of claims 12 or 15 in a carrier tracking module.

26. The carrier tracking module of claim 25 in a receiver.

27. The receiver of claim 26 in a communications device.

28. A set-top box which comprises the communications device of claim 27.

29. A system comprising:
a symbol estimation module for determining, for a multi-dimensional symbol rₖ^{D} having D dimensions, where D is an integer greater than 1, an estimate of the multi-dimensional symbol;
a residual determination module coupled to the symbol estimation module for determining a residual or a function thereof for the multi-dimensional symbol responsive to the multi-dimensional symbol rₖ^{D} and the estimate; and
a phase determination module for determining a derotation phase or phase offset estimate for the multi-dimensional symbol responsive to the residual or function thereof.

30. The system of claim 29 further comprising a symbol derotator for derotating each of the individual symbols in the multi-dimensional symbol rₖ^{D} responsive to the derotation phase.

31. The system of claim 29 further comprising an accumulator for determining a derotation phase for the multi-dimensional symbol responsive to the phase offset estimate.

32. The system of claim 31 further comprising a symbol derotator for derotating each of the individual symbols in the multi-dimensional symbol responsive to the derotation phase.

33. A system comprising:
symbol estimation means for determining, for a multi-dimensional symbol rₖ^{D} having D dimensions, where D is an integer greater than 1, an estimate of the multi-dimensional symbol;
residual determination means coupled to the symbol estimation means for determining a residual or a function thereof for the multi-dimensional symbol responsive to the multi-dimensional symbol rₖ^{D} and the estimate.

34. A method comprising the steps of:
determining, for a multi-dimensional symbol, an estimate of the symbol; and
determining, responsive to the estimate, a residual or a function thereof.

35. The method of claim 34 wherein the multi-dimensional symbol estimate comprises the vector sₖ^{D}.

36. The method of claim 34 wherein the multi-dimensional symbol estimate comprises the scalar sₖ.

37. The method of claim 34 wherein the residual comprises the residual vector zₖ^{D}.

38. The method of claim 34 wherein the residual comprises the scalar zₖ.

39. The method of claim 34 wherein the residual is a phase residual.

40. The method of claim 34 wherein the residual is an orthogonal component residual.

41. The method of claim 38 wherein the residual zₖ is a composite residual.

42. The method of claim 34 further comprising determining a function of the residual vector rₖ^{D}.

43. The method of claim 34 further comprising determining the average of the individual components of the residual vector rₖ^{D}.

44. The method of claim 34 further comprising determining a reliability metric Rₖ for the estimate of the multi-dimensional symbol, and weighting the residual or function thereof using the reliability metric.

45. The method of claim 34 further comprising determining a derotation phase responsive to the residual.

46. The method of claim 45 wherein the derotation phase is the vector θₖ^{D}.

47. The method of claim 45 wherein the derotation phase is the scalar θₖ.

48. The method of claim 34 further comprising determining a phase offset estimate responsive to the residual.

49. The method of claim 48 wherein the phase offset estimate is the vector Δθₖ^{D}.

50. The method of claim 48 wherein the phase offset estimate is the scalar Δθₖ.

51. The method of claim 45 further comprising derotating each of the individual symbols in the vector rₖ^{D} responsive to the derotation phase.

52. The method of claim 48 further comprising determining a derotation phase responsive to the phase offset estimate.

53. The method of claim 52 further comprising derotating each of the individual symbols in the vector rₖ^{D} responsive to the derotation phase.

54. The method of claim 45 further comprising updating the derotation phase at the frequency of individual symbols in the multi-dimensional symbol.

55. The method of claim 45 further comprising updating the derotation phase once for each multi-dimensional symbol.

56. A computer readable medium tangibly embodying any of the methods of claims 34-55.

57. The computer readable medium of claim 56 which comprises a memory.

58. Circuitry which tangibly embodies any of the methods of claims 34-55.
